(19) United States
(12) Patent Application Publication
(10) Pub. No.: US 2021/0141304 A1
(43) Pub. Date: May 13, 2021

(54) MASK STRIPS, ARRAY SUBSTRATES AND DISPLAY SCREENS

(71) Applicant: KunShan Go-Visionox Opto-Electronics Co., Ltd., Kunshan (CN)

(72) Inventors: Mingxing LIU, Kunshan (CN); Rusheng LIU, Kunshan (CN); Bing ZHANG, Kunshan (CN); Bing HAN, Kunshan (CN); Ying ZHAO, Kunshan (CN); Shuaiyan GAN, Kunshan (CN); Feng GAO, Kunshan (CN)

(73) Assignee: KunShan Go-Visionox Opto-Electronics Co., Ltd., Kunshan (CN)

(21) Appl. No.: 17/152,995

(22) Filed: Jan. 20, 2021

Related U.S. Application Data
(63) Continuation of application No. PCT/CN2019/098343, filed on Jul. 30, 2019.

(30) Foreign Application Priority Data
Jan. 31, 2019 (CN) 201910097878.4

(51) Int. Cl. G03F 1/38; H01L 27/32; H01L 51/00; H01L 51/52; H01L 51/56

(52) U.S. Cl. CPC G03F 1/38; H01L 27/3234; H01L 27/326; H01L 51/0011; H01L 2251/558; H01L 51/5221; H01L 51/5253; H01L 51/56; H01L 51/5206

(57) ABSTRACT

A mask strip, an array substrate, a display screen, and a display device. The mask strip is used for fabricating a light emitting structure layer on an array substrate. The mask strip includes a plurality of sub-masks, and each of the plurality of the sub-masks includes a first mask region and a second mask region, the first mask region has a plurality of first mask openings, the second mask region has a plurality of second mask openings. A second density of the second mask openings in the second mask region is less than a first density of the first mask openings in the first mask region, a second size of each of at least part of the second mask openings is larger than a first size of each of the plurality of first mask openings.

### CROSS REFERENCE TO RELATED APPLICATIONS

This patent application is a continuation application of International Application No. PCT/CN2019/098343, filed on Jul. 30, 2019, which claims priority to Chinese Patent Application No. 201910097878.4, filed on Jan. 31, 2019, both of them are incorporated herein by reference in their entireties.

### FIELD

The present application relates to a field of displays, in particular to mask strips, array substrates, and display screens.

### BACKGROUND

With the rapid development of display terminals, users have increasingly higher requirements on a screen-to-body ratio, so that full-screen display of display terminal has received more and more attention from the industry. For a display terminal such as a mobile phone and a tablet computer, because a front camera, an earphone, an infrared sensing element and the like need to be integrated therein, a display screen of the display terminal may be notched to place the front camera, the earphone, the infrared sensing element and the like. However, a notched area of the display screen may not be used to display pictures. Or a hole may be opened in the display screen to place the camera and the like. With respect to an electronic device implementing a camera function, external light may enter a photosensitive element placed below the screen through the hole in the screen. As such, the display screen of such a display terminal is not a full screen.

### SUMMARY

In view of this, the present application provides a mask strip, an array substrate, and a display screen.

A first aspect of the present application provides a mask strip for fabricating a light emitting structure layer on an array substrate, the mask strip includes a plurality of sub-masks, and each of the plurality of sub-masks includes a first mask region having a plurality of first mask openings; and a second mask region having a plurality of second mask openings, wherein a density of the second mask openings in the second mask region is less than a density of the first mask openings in the first mask region, and a size of each of at least part of the second mask openings is larger than a size of each of the plurality of first mask openings.

A second aspect of the present application provides an array substrate. The array substrate includes a substrate, a first OLED region and a second OLED region. Where the first OLED region includes: a first electrode layer formed on the substrate; a first light emitting structure layer formed on the first electrode layer; a first pixel opening, at least partial of the first light emitting structure layer being disposed within the first pixel opening; and a second electrode layer formed on the first light emitting structure layer, where the second OLED region includes: a third electrode layer formed on the substrate; a second light emitting structure layer formed on the third electrode layer; a second pixel opening, at least partial of the second light emitting structure layer being disposed within the second pixel opening; and a fourth electrode layer formed on the second light emitting structure layer. A pixel density in the first OLED region is greater than a pixel density in the second OLED region, and the first light emitting structure layer and the second light emitting structure layer are fabricated in a same process by using the mask strip as described above.

A third aspect of the present application provides a display screen. The display screen includes an array substrate mentioned before, and an encapsulation structure covering a surface of the array substrate.

### BRIEF DESCRIPTION OF THE DRAWINGS

FIG. 1 is a schematic top view of a sub-mask of a mask strip.

FIG. 2 is a schematic top view of an embodiment of a mask strip of the present application.

FIG. 3 is a schematic top view of an embodiment of a sub-mask of the present application.

FIG. 4 is a schematic top view of another embodiment of the sub-mask of the present application.

FIG. 5 is a schematic top view of yet another embodiment of the sub-mask of the present application.

FIG. 6 is a schematic top view of another embodiment of the sub-mask of the present application.

FIG. 7 is a schematic top view of another embodiment of the sub-mask of the present application.

FIG. 8 is a schematic top view of still another embodiment of the sub-mask of the present application.

FIG. 9 is a schematic top view of an embodiment of a second mask region of a sub-mask of the present application.

FIG. 10 is a schematic cross-sectional view of an embodiment of an array substrate of the present application.

FIG. 11 is a schematic top view of an embodiment of a first mask opening and a second mask opening of the present application.

FIG. 12 is a schematic top view of another embodiment of the first mask opening and the second mask opening of the present application.

FIG. 13 is a schematic top view of an embodiment of a third electrode layer of the present application.

FIG. 14 is a schematic top view of still another embodiment of the first mask opening and the second mask opening of the present application.

FIG. 15 is a schematic top view of another embodiment of a first pixel opening and the first mask opening of the present application.

FIG. 16 is a schematic top view of another embodiment of a second pixel opening and the second mask opening of the present application.

FIG. 17 is a schematic cross-sectional view of an embodiment of a display screen of the present application.

FIG. 18 is a schematic front view of an embodiment of a display device of the present application.

### DETAILED DESCRIPTION

In order to achieve a full screen, in the present application, a display area corresponding to a photosensitive component is set as a transparent display area with a low pixel density, so that the photosensitive component collects light transmitting through the transparent display area, while a normal display area outside or around the transparent display area has a standard pixel density. Referring to FIG. 1, the pixel density may be reduced by reducing a number of light emitting structures of the display area corresponding to the photosensitive component, thereby the transparent display area with the low pixel density is obtained. Specifically, a density of second mask openings 21 in second mask region 2 of a sub-mask of a mask strip corresponding to the transparent display area may be reduced, while a density of first mask openings 11 in first mask region 1 of the sub-mask of the mask strip corresponding to the normal display area may remain unchanged, where the density of the first mask openings (or the second mask openings) may be interpreted as a number of the first mask openings (or second mask openings) per unit area of first mask region 1 (or of second mask region 2). Further, due to the density of the second mask openings is different from the density of the first mask openings, when the mask strip is tensioned, stress across a boundary area between first mask region 1 and second mask region 2 of each sub-mask is uneven, and a wrinkle is easily formed in the boundary area, resulting in a high risk of color mixing at the boundary area between the normal display area and the transparent display area of the display screen. The above mask strip includes a plurality of sub-masks, and the plurality of sub-masks are connected with each other to form the mask strip as a whole.

In order to solve the above technical problems, an embodiment provides a mask strip for fabricating a light emitting structure layer on an array substrate. The mask strip includes a plurality of sub-masks, and each of the sub-masks includes a first mask region and a second mask region. The first mask region has a plurality of first mask openings, and the second mask region has a plurality of second mask openings. The density of the second mask openings in the second mask region is less than the density of the first mask openings in the first mask region, and a size of each of at least part of the second mask openings is larger than a size of each of the plurality of the first mask openings.

The density of the first mask openings in the first mask region is larger, and the density of the second mask openings in the second mask region is smaller. If the size of the first mask openings is equal to the size of the second mask openings, a strength of the second mask region is greater than a strength of the first mask region. In the present application, the size of each of the at least part of the second mask openings is larger than the size of each of the plurality of the first mask openings, thereby the strength of the second mask region is reduced and the second mask region is close to or equal to the strength of the first mask region. When the mask strip is tensioned, the boundary area between the first mask region and the second mask region of the sub-mask is subjected to even stress, so that it is not easy for the wrinkle to form in the boundary area. Thereby, the risk of color mixing at the boundary area between the transparent display area and the normal display area of the display screen is reduced or eliminated.

Embodiments of the present application provide a mask strip, which is used for fabricating a light emitting structure layer of an array substrate. As shown in FIGS. 10 and 11 described below, the array substrate includes a substrate 3, a first OLED region A located on the substrate 3, and a second OLED region B located on the substrate 3. The first OLED region A is a non-transparent display area (also referred to as a normal display area), and the second OLED region B is a transparent display area. Please refer to FIG. 2, the mask strip includes a plurality of sub-masks 10, and the plurality of sub-masks 10 are connected with each other to form the mask strip as a whole.

Please refer to FIG. 3, sub-mask 10 includes a first mask region 1a, a second mask region 2a, and a non-mask functional region 9a. Non-mask functional region 9a serves as a connection region between adjacent sub-masks. Non-mask functional region 9a is corresponding to a non-display area of the display screen, and a light emitting structure is not to be fabricated in an evaporation process on the non-mask functional region. The first light emitting structure layer of the first OLED region is fabricated on first mask region 1a, and the second light emitting structure layer of the second OLED region is fabricated on second mask region 2a. First mask region 1a completely surrounds second mask region 2a. In other embodiments, the first mask region may partially surround the second mask region.

Referring to FIG. 3, in this embodiment, first mask region 1a includes a plurality of first mask openings 11a, and second mask region 2a includes a plurality of second mask openings 21a. A shape of a first mask opening 11a and a shape of a second mask opening 21a are both circular, and a size of second mask opening 21a is larger than a size of first mask opening 11a. The size here may refer to radius or area of a circle of the mask opening. In other embodiments, the first mask opening and the second mask opening may be in another shape such as square and triangle, and the size of the mask opening may refer to an area or a side length of the mask opening. In this embodiment, by increasing the sizes of second mask openings 21a in second mask region 2a, a strength of second mask region 2a is reduced to be close to or equal to a strength of first mask region 1a, uneven stress across the boundary area between first mask region 1a and second mask region 2a is avoided, thereby the risk of color mixing between the first OLED region and the second OLED region is reduced or eliminated.

In some embodiments, an arrangement pattern of the second mask openings is substantially same as an arrangement pattern of the first mask openings, for example, the arrangement pattern of second mask openings 21a is roughly the same as the arrangement pattern of first mask openings 11a shown in FIG. 3. For example, the mask openings are all arranged in a straight line, or the mask openings are in triangular arrangement. In other embodiments, the arrangement pattern of the second mask openings is different from the arrangement pattern of the first mask openings.

A relationship between the size of second mask openings 21a and the size of first mask openings 11a may be adjusted adaptively by a difference in pixel density between the first OLED region and the second OLED region, so that the strength of second mask region 2a is close to or equal to the strength of first mask region 1a.

Referring to FIG. 4, in another embodiment, the shape of first mask openings 11b in first mask region 1b of the sub-mask and the shape of second mask openings 21b in second mask region 2b of the sub-mask are both rectangular, and other structures of the sub-mask are same as the structures in the embodiment shown in FIG. 3.

Referring to FIG. 5, the structure of first mask region 1c is same as that of first mask region 1a in the embodiment of FIG. 3, and second mask region 2c includes at least two regions with openings and arranged sequentially from a center region to an outer region in second mask region 2c. In two adjacent regions with openings, a size of the second mask openings in the region with openings close to the center region is smaller than a size of the second mask openings in the region with openings away from the center region. The region with openings away from the center region at least partially surrounds the region with openings close to the center region.

As shown in FIG. 5, second mask region 2c includes first region with openings 201c and second region with openings 202c that are adjacent to each other, and the size of second mask openings 211c in the first region with openings 201c close to the center region is smaller than the size of second mask openings 212c in the second region with openings 202c away from the center region. In an embodiment, second mask region 2c further includes a third region with openings 203c, and a distance between third region with openings 203c and the center region is farther than a distance between second region with openings 202c and the center region. A size of second mask openings 212c in the second region with openings 202c is smaller than a size of second mask openings 213c in third region with openings 203c. First mask region 11c surrounds third region with openings 203c, third region with openings 203c surrounds second region with openings 202c, and second region with openings 202c surrounds first region with openings 201c.

With continued reference to FIG. 5, a size of second mask openings 211c in first region with openings 201c located in the center region of second mask region 2c is equal to the size of the first mask openings 11c. In other embodiments, the size of the second mask openings 211c in first region with openings 201c located in the center region of second mask region 2c is larger than the size of the first mask openings.

In a direction from outside to inside of the second mask region (as shown in an arrow direction of FIG. 5), since the sizes of the second mask openings 213c, 212c, and 211c are sequentially reduced, a strength of third region with openings 203c, a strength of second region with openings 202c and a strength of first region with openings 201c are increased sequentially. The strength of the first mask region 1c is substantially equal to that of the third region with openings 203c. The strength of third region with openings 203c is slightly less than the strength of second region with openings 202c, and the strength of second region with openings 202c is slightly less than the strength of first region with openings 201c. In other words, for all regions with openings on the sub-mask, the strengths of respective regions with openings gradually increase from outside to inside, and a strength difference between two adjacent regions with openings is small, so that stress distribution across the boundary area in respective regions with openings on the sub-mask is relatively even, and it is not easy for color mixing phenomenon to occur in a region of the array substrate generated by the mask strip and corresponding to the boundary area.

The structure of the sub-mask shown in FIG. 6 is substantially same as the structure of the sub-mask shown in FIG. 5. The shape of the mask openings and the shape of the second mask region of the sub-mask shown in FIG. 5 are both circular. A shape of first mask region 1d and a shape of second mask region 2d of the sub-mask shown in FIG. 6 are square, and the shape of the first mask openings and the shape of the second mask openings are both square. Second mask region 2d includes first region with openings 201d, second region with openings 202d, and third region with openings 203d sequentially arranged outwards from a center region. In other embodiments, the shapes of the first mask region and the second mask region, and the shapes of the first mask openings and the second mask openings may be changed according to actual needs, and the shape of the first mask openings may be same as or different from the shape of the second mask openings, for example, the shape of the first mask openings and the shape of the second mask openings are all square, or the shape of the first mask openings is square, and the shape of the second mask openings is circular, oval, dumbbell-shaped or gourd-shaped.

Please refer to FIG. 7, in this embodiment, the sub-mask includes first mask region 1e, second mask region 2e and non-mask functional region 9e, where second mask region 2e is located between first mask region 1e and non-masked functional region 9e. Non-mask functional region 9e is provided with a plurality of through holes 91e. In this embodiment, sizes of the plurality of through holes 91e are equal, and the size of the through hole 91e is smaller than a size of second mask opening 21e in second mask region 2e and larger than a size of first mask opening 11e in first mask region 1e. By providing through holes 91e on non-mask functional region 9e, the entire sub-mask is subjected to even stress during the tensioning process of the mask strip, so that the risk of color mixing of the array substrate caused by wrinkling of the sub-mask is avoided.

In the sub-mask shown in FIG. 8, the structures of first mask region 1f and second mask region 2f are identical to the structures of first mask region 1e and second mask region 2e in the foregoing embodiment, which are not described again. Non-mask functional region 9f is provided with a plurality of through holes 91f. Through holes 91f includes first through holes 911f, second through holes 912f, and third through holes 913f arranged in a direction away from second mask region 2f, and a size of first through holes 911f, a size of second through holes 912f and a size of third through holes 913f are sequentially reduced. In other words, in the direction away from second mask region 2f, the strength of the non-mask functional region gradually increases from the strength of the second mask region, thereby the strength distribution of each region across the entire sub-mask is even, so that the entire sub-mask is subjected to even stress during the tensioning process of the mask strip, and the risk of color mixing of the array substrate caused by wrinkling of the sub-mask is avoided.

In other embodiments, the through holes shown in FIG. 7 or FIG. 8 may be replaced by recesses. The recesses may be understood as retaining a part of material of the through hole, and the structure of a recess is similar to a blind hole. In some embodiments, the recesses may be used instead of some of the through holes. By setting the recesses, the entire sub-mask is subjected to even stress during the tensioning process of mask strip, so that the risk of color mixing of the array substrate caused by wrinkling of the sub-mask is avoided.

In an embodiment, the shape of the through holes or recesses is circular, oval, dumbbell-shaped, gourd-shaped, or square. The shape of the through holes or recesses may be same as or different from the shape of the second mask openings. When the shape of the through holes or recesses is same as the shape of the second mask openings, the stress distribution of the sub-mask is more even.

Referring to FIG. 9, the second mask region 2g is provided with a plurality of second mask openings 21g and a plurality of mask recesses 22g. In this implementation, each of mask recesses 22g is located between adjacent second mask openings 21g, and the structure of mask recesses 22g is similar to the structure of the recesses in the foregoing embodiment. By providing mask recess 22g between two adjacent second mask openings 21g, the strength of second mask region 2g is close to or equal to the strength of the first mask region, which is beneficial to alleviate internal stress of the sub-mask, thereby the risk of color mixing between the first OLED region and the second OLED region of the array substrate is reduced, and at the same time, position accuracy of second mask openings 21g affected by the uneven stress of the sub-mask is avoided. In an embodiment, the size of mask recesses 22g is same as the size of second mask openings 21g, which is beneficial to simplify the fabricating process of the sub-mask and to make the stress distribution in the second mask region 2g even.

In an embodiment, referring to FIG. 9, the second OLED region B (refer to FIG. 10) of the array substrate includes a plurality of pixel units, each pixel unit includes n sub-pixels, and second mask region 2g includes a plurality of second mask sub-regions 20g, each of which is corresponding to one pixel unit. The number of mask recesses 22g in each second mask sub-region 20g is n-1, that is, the number of mask recesses 22g is less than the number of second mask openings 21g by one. For example, n is equal to 3, that is, when the number of second mask openings 21g is three, the number of mask recesses in each second mask sub-region is two. In some embodiments, n sub-pixels may be different sub-pixels in n colors. In other implementations, some of the n sub-pixels have a same color.

In an embodiment, a distance between mask recess 22g and adjacent second mask opening 21g is equal to a distance between adjacent two first mask openings, thereby the strength of second mask region 2g is more approximate to the strength of the first mask region, further reducing the risk of color mixing.

Please refer to FIG. 10, the present application also provides an array substrate 100. The array substrate includes a substrate 3, a first OLED region A located on substrate 3, and a second OLED region B located on substrate 3. The first OLED region A is a non-transparent display area (or referred to as a normal display area), and the second OLED region B is a transparent display area. The first OLED region A may be in a shape of circle, square, etc., and the second OLED region B may be in a shape of circle, square, water drop, notch-shaped or fringe-shaped, etc. The first OLED region A surrounds the second OLED region B. In other embodiments, the first OLED region partially surrounds the second OLED region.

Substrate 3 may include a base substrate, a driving circuit layer (such as a thin film transistor), an organic layer, an inorganic layer, and other structures. The portion of the substrate corresponding to the second OLED region B may not be provided with the driving circuit layer, but wiring for the portion may be configured in other film layers or non-display area. The first OLED region A includes a first electrode layer 4 formed on substrate 3, a first light emitting structure layer 61 formed on first electrode layer 4, and a second electrode layer 7 formed on first light emitting structure layer 61. The second OLED region B includes a third electrode layer 5 formed on substrate 3, a second light emitting structure layer 62 formed on third electrode layer 5, and a fourth electrode layer 8 formed on second light emitting structure layer 62. First light emitting structure layer 61 and second light emitting structure layer 62 are formed in a same process using the sub-mask.

Substrate 3 may be a rigid substrate, for example, a transparent substrate such as a glass substrate, a quartz substrate, or a plastic substrate. In another embodiment, substrate 3 may be a flexible substrate, such as a flexible Polyimide (PI) substrate.

In an embodiment, in order to improve light transmittance of the second OLED region, materials of conductive wires (for example, third electrode layer 5 and fourth electrode layer 8) in the second OLED region may include transparent materials. The light transmittance of the third electrode layer and the light transmittance of the fourth electrode layer are greater than 40%. Further, the light transmittance of the two is greater than 60%. Still further, the light transmittance of the two is not less than 80%. For example, the materials of the third electrode layer and the fourth electrode layer may include a transparent conductive metal oxide or a magnesium-silver mixture. For example, the materials of the third electrode layer and the fourth electrode layer may include at least one of indium tin oxide (ITO), indium zinc oxide (IZ), silver-doped indium tin oxide, and silver-doped indium zinc oxide. In this embodiment, first electrode layer 4 and third electrode layer 5 are anodes, and second electrode layer 7 and fourth electrode layer 8 are cathodes. In other embodiments, first electrode layer 4 and third electrode layer 5 are cathodes, and second electrode layer 7 and fourth electrode layer 8 are anodes.

In an embodiment, fourth electrode layer 8 is a planar electrode. Optionally, fourth electrode layer 8 has a single-layer structure or a stacked structure. If fourth electrode layer 8 has a single-layer structure, the fourth electrode layer 8 is one of the following: a single-layer metal layer, a single-layer metal mixture layer, and a single-layer transparent metal oxide layer. If fourth electrode layer 8 has a stacked structure, the fourth electrode layer 8 is one of the following: a stack of transparent metal oxide layer and metal layer, and a stack of transparent metal oxide layer and metal mixture layer.

In an embodiment, when a material of fourth electrode layer 8 is doped with metal, and a thickness of fourth electrode layer 8 is greater than or equal to 100 Å and less than or equal to 500 Å, the fourth electrode layer 8 is an overall continuous planar electrode, and a transmittance of fourth electrode layer 8 is greater than 40%. When the material of fourth electrode layer 8 is doped with metal, and the thickness of fourth electrode layer 8 is greater than or equal to 100 Å and less than or equal to 200 Å, the fourth electrode layer 8 is an overall continuous planar electrode, and the transmittance of fourth electrode layer 8 is greater than 40%. When the material of fourth electrode layer 8 is doped with metal, the thickness of fourth electrode layer 8 is greater than or equal to 50 Å and less than or equal to 200 Å, the fourth electrode layer 8 is an overall continuous planar electrode, and the transmittance of fourth electrode layer 8 is greater than 50%. When the material of fourth electrode layer 8 is doped with metal, and the thickness of fourth electrode layer 8 is greater than or equal to 50 Å and less than or equal to 200 Å, the fourth electrode layer 8 is an overall continuous planar electrode, and the transmittance of fourth electrode layer 8 is greater than 60%. If fourth electrode layer 8 has a single-layer structure, the material of the single-layer metal layer is Al or Ag, and the material of the single-layer metal mixture layer is Mg, Ag or Al-doped metal mixed material, and the material of single-layer transparent metal oxide layer is ITO or IZO.

Referring to FIG. 11, the first OLED region A includes a plurality of first pixel openings 601, and the second OLED region B includes a plurality of second pixel openings 602. A portion of the first light emitting structure layer is disposed in each of the plurality of first pixel openings 601, and a portion of the second light emitting structure layer is disposed in each of the plurality of second pixel openings 602. The pixel openings are formed by a pixel defining layer (not shown) formed on first electrode layer 4 and third electrode layer 5, and a light emitting area is determined by a size of each pixel opening. Other portions of the first light emitting structure layer and the second light emitting structure layer are formed on a portion of the pixel defining layer without pixel openings. An arrangement pattern of second pixel openings 602 is same as an arrangement pattern (or arrangement manner) of first pixel openings 601. In this embodiment, both the first OLED region A and the second OLED region B are AMOLED (Active Matrix Organic Light Emitting Diode) areas.

Please refer to FIG. 10 and FIG. 11, a size of second pixel openings 602 is same as a size of first pixel openings 601. The driving circuit of first electrode layer 4 in the first OLED region and the driving circuit of third electrode layer 5 in the second OLED region may both be 7T1C (7 transistors and 1 capacitor) driving circuits. In some embodiments, the driving circuit of third electrode layer 5 in the second OLED region is a 2T1C driving circuit; or, the driving circuit of third electrode layer 5 in the second OLED region includes a TFT. The array substrate includes scan lines and data lines. In a case where the driving circuit of third electrode layer 5 in the second OLED region includes a TFT, the data line is electrically connected with a source of the TFT, the third electrode layer is electrically connected with a drain of the TFT, and the scan line is electrically connected with a gate of the TFT. The scan line is used to control the on and off of the driving circuit, and the data line is used to, when the driving circuit is turned on, provide driving current to the third electrode layer to control the light emitting structure layer to emit light. A number of switching components (for example, transistors) in the driving circuit is reduced to two or one. In this way, a complexity of the panel structure is simplified and a degree of diffraction caused by gaps in the panel structure is reduced, and a load current of the scan line and a load current of the data line are greatly reduced, thereby resistance requirements for anode, cathode, scan line, data line and other conductive wire materials are decreased, so that transparent materials may be used to fabricate anode, cathode, scan line, data line and other conductive wires. Performance of a display panel is ensured while transmittance of the display panel is improved. The first OLED region is an AMOLED area, and the second OLED region is an AMOLED area or a PMOLED (Passive matrix Organic Light Emitting Diode) area. In other embodiments, the data line is electrically connected with the drain of the TFT, the third electrode layer is electrically connected with the source of the TFT, and the scan line is electrically connected with the gate of the TFT.

In another embodiment, please refer to FIG. 12, a size of each of the plurality of second pixel openings 602a in the second OLED region B1 is larger than a size of each of the plurality of first pixel openings 601a in the first OLED region A1. Correspondingly, the third electrode layer of the second OLED region B1 includes a plurality of strip-shaped third electrodes 51a, as shown in FIG. 13. Each strip-shaped third electrode 51a corresponds to a plurality of second light emitting structures of second light emitting structure layer 62, and each strip-shaped third electrode 51a corresponding to the plurality of second light emitting structures may be driven by one same driving circuit, thereby the number of driving circuits is reduced.

Second pixel openings 602 and 602a shown in FIG. 11 and FIG. 12 have a square shape. In other embodiments, the shape of the second pixel openings is circular, oval, or dumbbell-shaped.

Referring to FIG. 14, when the size of the second pixel openings is larger than the size of the first pixel openings, the second OLED region B2 includes at least two display areas arranged sequentially from a center region to an outer region in the second OLED B2, and in two adjacent display areas, the size of the second pixel openings in a display area close to the center region is smaller than the size of the second pixel openings in a display area away from the center region. In this embodiment, the second OLED region B2 includes a first display area B21, a second display area B22 and a third display area B23 arranged sequentially from the center region to the outer region in the second OLED region B2. A size of each of a plurality of second pixel openings 6021b in first display area B21 is smaller than a size of each of a plurality of second pixel openings 6022b in second display area B22, and the size of each of the plurality of second pixel openings 6022b in second display area B22 is smaller than a size of each of a plurality of second pixel openings 6023b in third display area B23. In some other embodiments, the second OLED region B2 may be provided with only the first display area and the second display area, or may be provided with more display areas.

In this embodiment, the size of the second pixel openings 6021b in the first display area is larger than the size of first pixel openings 601b. In other embodiments, the size of the second pixel openings in the center region of the second OLED region B may also be equal to the size of the first pixel openings.

With reference to FIG. 4, FIG. 15 and FIG. 16, a second distance between a first outer contour of projection of second mask opening 21b in the above sub-mask on substrate 3 and a second outer contour of projection of second pixel opening 602 on substrate 3 mask is d2, a first distance between a third outer contour of projection of first mask opening 11b in the above sub-mask on substrate 3 and a fourth outer contour of projection of first pixel opening 601 on substrate 3 mask is d1, where d2 is larger than d1. In an embodiment, the range of d1 is 3 μm-6 μm, and the range of d2 is 8 μm-15 μm. When the range of d2 is from 8 μm to 15 μm, the strength of first mask region 1b of the sub-mask is approximately equal to the strength of second mask region 2b of the sub-mask, which is beneficial to eliminate the risk of color mixing between the first OLED region and the second OLED region of the array substrate.

The present application also provides a display screen 200. As shown in FIG. 17, the display screen includes an array substrate 100 and an encapsulation structure 201 covering a surface of the array substrate. A photosensitive component such as a camera and a sensor may be provided below the second OLED region B, and the photosensitive component may collect external light transmitting through the transparent second OLED region B. A display function is realized while performance of the photosensitive component is ensured.

With reference to FIG. 18, the present application further provides a display device. The display device includes a device main body C and a display screen 200 covering the device main body. The display device may be a device such as a mobile phone, a tablet computer, a notebook computer, etc. Taking a mobile phone as an example, the device main body C may include components such as a housing, a circuit board, a battery, a processor, etc. The device main body C has a component area 300. The component area is located below the second OLED region, and the component area 300 is provided with a photosensitive component D that collects light transmitting through the second OLED region. Due to the high light transmittance of the second OLED region, collecting enough light by the photosensitive component may be ensured, thereby the performance of the photosensitive component is ensured.

The above descriptions are only some embodiments of the present application and are not intended to limit the present application. Any modification, equivalent replacement, improvement, etc. made within the spirit and principle of the present application should be included in the present application within the scope of protection.

1. A mask strip, for fabricating a light emitting structure layer on an array substrate, comprising a plurality of sub-masks, wherein each of the plurality of sub-masks comprises:
a first mask region, having a plurality of first mask openings; and
a second mask region, having a plurality of second mask openings,
wherein a density of the second mask openings in the second mask region is less than a density of the first mask openings in the first mask region, and a size of each of at least part of the second mask openings is larger than a size of each of the plurality of first mask openings.

2. The mask strip of claim 1, wherein,
a distance between an outer contour of projection of each of the second mask openings on the array substrate and an outer contour of projection of a corresponding one of the second pixel openings corresponding to the second mask openings on the array substrate is 8 μm to 15 μm.

3. The mask strip of claim 1, wherein,
an arrangement pattern of the plurality of second mask openings is same as an arrangement pattern of the plurality of first mask openings.

4. The mask strip of claim 1, wherein the second mask region comprises at least two regions with openings arranged sequentially from a center region to an outer region in the second mask region, and in any two adjacent ones of the at least two regions with openings, a size of each of the second mask openings in a second region with openings close to the center region is smaller than a size of each of the second mask openings in a first region with openings away from the center region.

5. The mask strip of claim 4, wherein,
a size of each of the second mask openings in the center region of the second mask region is greater than or equal to the size of each of the first mask openings.

6. The mask strip of claim 1, wherein each of the sub-masks further comprises a non-mask functional region, the second mask region is located between the non-mask functional region and the first mask region, and the non-mask functional region is provided with a plurality of through holes or a plurality of recesses.

7. The mask strip of claim 6, wherein,
a size of each of the plurality of through holes or recesses is equal to each other; or
sizes of the plurality of through holes or recesses gradually decrease in a direction away from the second mask region.

8. The mask strip of claim 6, wherein,
a size of each of the through holes or the recesses is smaller than the size of each of the second mask openings in the second mask region, and larger than the size of each of the first mask openings in the first mask region.

9. The mask strip of claim 1, wherein the second mask region comprises a plurality of mask recesses and each of the plurality of mask recesses is located between adjacent ones of the second mask openings.

10. The mask strip of claim 9, wherein,
a size of each of the mask recesses is equal to the size of each of the second mask openings.

11. The mask strip of claim 9, wherein,
the second mask region comprises a plurality of second mask sub-regions corresponding to pixel units of the array substrate, and a number of the mask recesses is less than a number of the second mask openings by one in each of the second mask sub-regions.

12. The mask strip of claim 9, wherein,
a distance between a mask recess and a second mask opening which are adjacent is equal to a distance between adjacent two first mask openings.

13. An array substrate, comprising:
a substrate;
a first OLED region, comprising:
a first electrode layer formed on the substrate;
a first light emitting structure layer formed on the first electrode layer;
a plurality of first pixel openings, a portion of the first light emitting structure layer being disposed within each of the plurality of the first pixel openings; and
a second electrode layer formed on the first light emitting structure layer; and
a second OLED region, comprising:
a third electrode layer formed on the substrate;
a second light emitting structure layer, formed on the third electrode layer;
a plurality of second pixel openings, a portion of the second light emitting structure layer being disposed within each of the plurality of the second pixel openings; and
a fourth electrode layer, formed on the second light emitting structure layer;
wherein a pixel density in the first OLED region is greater than a pixel density in the second OLED region, and the first light emitting structure layer and the second light emitting structure layer are fabricated in a same process by using the mask strip of claim 1.

14. The array substrate of claim 13, wherein an arrangement pattern of the second pixel openings is same as an arrangement pattern of the first pixel openings.

15. The array substrate of claim 13, wherein,
a size of each of the second pixel openings is larger than or equal to a size of each of the first pixel openings.

16. The array substrate of claim 15, wherein,
when the size of each of the second pixel openings is larger than the size of each of the first pixel openings, the second OLED region comprises at least two display areas arranged sequentially from a center region to an outer region in the second OLED region, and in any two adjacent display areas in the at least two display areas, a size of each of the second pixel openings in a second display area close to the center region is smaller than a size of the second pixel openings in a first display area away from the center region.

17. The array substrate of claim 16, wherein,
a size of each of the second pixel openings in the center region of the second OLED region is larger than or equal to the size of each of the first pixel openings.

18. The array substrate of claim 13, wherein,
the first electrode layer and the third electrode layer are anodes, and the second electrode layer and the fourth electrode layer are cathodes;
the third electrode layer comprises a plurality of third electrodes, and the fourth electrode layer is a planar electrode;
the fourth electrode layer is a single-layer structure or a stack structure,
when the fourth electrode layer is a single-layer structure, the fourth electrode layer comprises one of the following:
a single-layer metal layer,
a single-layer metal mixture layer, or
a single-layer transparent metal oxide layer,
when the fourth electrode layer is a stack structure, the fourth electrode layer comprises one of the following:
a stack of transparent metal oxide layer and metal layer, or
a stack of transparent metal oxide layer and metal mixture layer;
when a material of the fourth electrode layer is doped with metal, and a thickness of the fourth electrode layer is greater than or equal to 100 Å and less than or equal to 500 Å, the fourth electrode layer is an integral continuous planar electrode, and a transmittance of the fourth electrode layer is greater than 40%;
when the material of the fourth electrode layer is doped with metal, and the thickness of the fourth electrode layer is greater than or equal to 100 Å and less than or equal to 200 Å, the fourth electrode layer is the integral continuous planar electrode, and the transmittance of the fourth electrode layer is greater than 40%;
when the material of the fourth electrode layer is doped with metal, and the thickness of the fourth electrode layer is greater than or equal to 50 Å and less than or equal to 200 Å, the fourth electrode layer is the integral continuous planar electrode, and the transmittance of the fourth electrode layer is greater than 50%;
when the material of the fourth electrode layer is doped with metal, and the thickness of the fourth electrode layer is greater than or equal to 50 Å and less than or equal to 200 Å, the fourth electrode layer is the integral continuous planar electrode, and the transmittance of the fourth electrode layer is greater than 60%; and
when the fourth electrode layer is a single-layer structure, a material of the single-layer metal layer is Al or Ag, a material of the single-layer metal mixture layer is Mg, Ag, or an Al-doped metal mixed material, and a material of single-layer transparent metal oxide layer is ITO or IZO.

19. A display screen, comprising:
an array substrate according to claim 13; and
an encapsulation structure covering a surface of the array substrate.
